(19) United States
(12) Patent Application Publication
(10) Pub. No.: US 2014/0103930 A1
(43) Pub. Date: Apr. 17, 2014

(54) VENTILATION DEVICE FOR MAGNETIC REASONANCE IMAGING SYSTEM AND MAGNETIC REASONANCE IMAGING SYSTEM

(71) Applicants: Jun Wang, Shenzhen (CN); Hai Ping Yin, Shenzhen (CN)

(72) Inventors: Jun Wang, Shenzhen (CN); Hai Ping Yin, Shenzhen (CN)

(21) Appl. No.: 14/051,557

(22) Filed: Oct. 11, 2013

(30) Foreign Application Priority Data
Oct. 11, 2012 (CN) 201210384133.4

(51) Int. Cl. G01R 33/28

(52) U.S. Cl. CPC G01R 33/28
USPC 324/318

(57) ABSTRACT

A ventilation device for an MRI system and an MRI system are presented. The ventilation device has a fan and an adjustment component. The fan is used to generate a flow of air past an examination subject in the MRI system, and the adjustment component is used to adjust an operating parameter of the fan according to a heat signal indicating variation of heat in the examination subject. The ventilation device and MRI system enhance the user's experience of the MRI system, increase the examination subject's ability to undergo examinations of high SAR and long duration, and reduce medical risks associa.

### CROSS REFERENCE TO RELATED APPLICATIONS

This application claims priority to Chinese application No. 2012 103 841 33.4 CN filed Oct. 11, 2012, the entire content of which is hereby incorporated herein by reference.

### FIELD OF INVENTION

The present invention relates to a magnetic resonance imaging system, in particular to a ventilation device for a magnetic resonance imaging system.

### BACKGROUND OF INVENTION

Magnetic resonance imaging (MRI) is a biomagnetic/nuclear spin imaging technology which has developed rapidly in pace with computer technology, electronic circuit technology and superconducting magnet technology. In MRI, tissue of the human body is placed in a static magnetic field B₀, and hydrogen atom nuclei in the human tissue are then excited by an RF pulse of a frequency equal to the precession frequency of the hydrogen atom nuclei. This causes the hydrogen atom nuclei to resonate and absorb energy; once the RF pulse ends, the hydrogen atom nuclei emit a radio signal of a specific frequency, releasing the absorbed energy. The signal is received and recorded by a receiver outside the body, and processed by a computer to obtain an image.

During scanning by an MRI system, some of the RF energy is absorbed by the examination subject. The specific absorption rate (SAR) has units of W/kg, and is used to evaluate the thermal effect produced by the MRI system on the examination system. When being scanned by the MRI system, the examination subject will heat up as a result of having absorbed RF energy, and consequently will feel hot. When the SAR is high, the examination subject may even sweat or feel extremely uncomfortable. In some cases, heat of this kind becomes difficult to bear, and the examination subject demands an immediate halt to the scan.

The development of MRI systems shows a trend towards stronger magnetic fields. The specific absorption rate (SAR) is approximately proportional to the square of the main magnetic field strength B₀, so the energy expended in the body of an examination subject by a 3 T nuclear magnetic resonance scanning system will be four times that expended by a 1.5 T system when the same examination program is used. Another trend evident in the development of MRI systems is increasing duration of examination procedures, which similarly implies greater expenditure of RF energy in the examination subject.

At present, some MRI systems are equipped with examination subject ventilation devices. These ventilation devices rely on one or more fans to produce a flow of air past the examination subject; the fans operate at a fixed airflow speed, direction and temperature, with the result that the examination subject may feel cold in the initial stages of the examination, but hot in the latter stages thereof after absorbing a large amount of RF energy, because the device is unable to take enough heat away from the surface of the examination subject's body effectively. Clearly, such a ventilation device does not allow operating parameters to be adjusted according to the situation so that the examination subject feels comfortable throughout the examination procedure.

### SUMMARY OF INVENTION

In view of the above, the present invention proposes a ventilation device for an MRI system, which ventilation device adjusts the airflow generated during the examination according to heat variation in the examination subject, to lower the body temperature of the examination subject and thereby make him/her feel more comfortable.

According to a first aspect of the present invention, a ventilation device for an MRI system is proposed, the ventilation device comprising a fan and an adjustment component, the fan being used to generate an airflow past an examination subject in the MRI system, and the adjustment component being used to adjust an operating parameter of the fan according to a heat signal indicating variation of heat in the examination subject.

According to another aspect of the present invention, an MRI system is proposed, comprising the above ventilation device.

Preferably, the MRI system comprises a patient table, comprising at least one airflow channel and/or at least one airflow through-hole, the airflow channel being located on a surface in contact with the examination subject and serves to permit the passage of an airflow; the airflow through-hole is perpendicular to a surface in contact with the examination subject, and serves to permit the passage of an airflow.

With the ventilation device and MRI system comprising the same according to the present invention, an examination subject will not feel uncomfortable because of temperature, thus the user's experience of the MRI system is enhanced. By the same token, the comfortable temperature increases the examination subject's ability to undergo examinations of high SAR and long duration. Evidently, the comfortable temperature also reduces medical risks associated with overheating of the body: for example, in some cases, high absorption of RF energy will lead to reddening or even burning of the skin. With the ventilation device based on particular embodiment 1 of the present invention, heat will be rapidly dissipated, thereby lowering the incidence of such risks. Many examination subjects are distressed during nuclear magnetic resonance examinations, and a flow of air can help to reduce such distress and the sense of being confined. However, with existing ventilation devices, the operator will sometimes forget to switch on the ventilation device or the fan rotation speed is too low; with the ventilation device based on particular embodiment 1 of the present invention, the airflow is automatically adjusted in the default state, and an optimized airflow can significantly reduce the distress felt by examination subjects.

### BRIEF DESCRIPTION OF THE DRAWINGS

Preferred embodiments of the present invention will be described below in detail with reference to the accompanying drawings, to give those skilled in the art a clearer understanding of the above and other features and advantages thereof. In the drawings:

FIG. 1 is a schematic diagram of an MRI system according to particular embodiment 1 of the present invention.

FIG. 2 is a schematic diagram of an MRI system according to particular embodiment 2 of the present invention.

FIG. 3 is an MRI system with a ventilation device according to particular embodiment 1 and particular embodiment 2.

main computer 100
ventilation device 200
imaging device 300
SAR monitoring/control and prediction component 101
bodily sign detection component 102
adjustment component 201
fan 202

### DETAILED DESCRIPTION OF INVENTION

The present invention is illustrated in further detail below by way of embodiments, to clarify the object, technical solution and advantages thereof.

At the heart of the present invention is a ventilation device for an MRI system, the ventilation device comprising an adjustment component and a fan, the adjustment component being used to adjust an operating parameter of the fan according to a heat signal from the MRI system.

FIG. 1 is a schematic diagram of an MRI system according to particular embodiment 1 of the present invention. As FIG. 1 shows, the MRI system comprises a main computer 100, a ventilation device 200 and an imaging device 300, wherein the main computer 100 is connected to the ventilation device 200 and the imaging device 300 separately. The main computer 100 comprises an SAR monitoring and prediction component 101, which monitors the SAR according to a scanning sequence which the examination subject has already undergone and predicts the SAR according to a scanning sequence which the examination subject will undergo, so as to find the RF energy already absorbed by the examination subject and the RF energy which will be absorbed by the examination subject. By means of the connection between the main computer 100 and the ventilation device 200, the SAR monitoring and prediction device 101 sends the above energy signal to the ventilation device 200 as a heat signal from the MRI system. The ventilation device 200 comprises an adjustment component 201 and a fan 202. By means of the connection between the main computer 100 and the ventilation device 200, the adjustment component 201 receives the energy signal outputted by the SAR monitoring and prediction component 101 of the main computer 100, and adjusts the airflow generated by the fan 202 of the ventilation device 200 according to the above signal, i.e. the RF energy already absorbed by the examination subject and the RF energy which will be absorbed by the examination subject. At the same time, the main computer 100 outputs a command for a scanning sequence to the imaging device 300, which subjects the examination subject to magnetic resonance imaging according to the scanning sequence. Preferably, the ventilation device 200 further comprises a refrigeration component, for refrigerating the airflow generated by the fan 202.

On the basis of the RF energy already absorbed by the examination subject and the RF energy which will be absorbed thereby, the adjustment component 201 adjusts the strength, direction and temperature of the airflow generated by the fan 202 of the ventilation device 200. If, on the basis of the energy signal outputted by the SAR monitoring and prediction component 101, the ventilation device 200 judges that the RF energy already absorbed by the examination subject is quite high or that the RF energy which will be absorbed thereby is quite high, i.e. judges that the RF energy already absorbed by the examination subject is greater than and/or equal to a specified threshold or that the RF energy which will be absorbed thereby is greater than and/or equal to a specified threshold, this indicates that the examination subject needs to be cooled; thus the ventilation device 200 will adjust the fan 202 to take heat away from the surface of the examination subject's body in an optimal manner, thereby ensuring the comfort of the examination subject. The adjustment component 201 of the ventilation device 200 can accomplish this task in one or more of the following ways, singly or in combination: (1) increasing the strength of the airflow, (2) adjusting the direction of the airflow, (3) lowering the temperature of the airflow. If, on the basis of the signal from the SAR monitoring and prediction component 101, the ventilation device 200 judges that the RF energy already absorbed by the examination subject is quite low or that the RF energy which will be absorbed thereby is quite low, i.e. judges that the RF energy already absorbed by the examination subject is lower than a specified threshold or that the RF energy which will be absorbed thereby is lower than a specified threshold, the examination subject either does not require cooling or requires to be heated; thus the ventilation device 200 will adjust the operating parameters of the fan and/or the refrigeration component in the opposite direction, thereby ensuring the comfort of the examination subject. In addition to default options for automatic adjustment, the operator may adjust the ventilation device manually if the examination subject has special needs.

The SAR monitoring and prediction component 101 is already used widely in nuclear magnetic resonance imaging systems, being used to monitor the SAR according to the scanning sequence already undergone by the examination subject, or to predict the SAR according to the scanning sequence which the examination subject will undergo.

In the ventilation device according to particular embodiment 1 of the present invention, operating parameters of the fan are adjusted according to the needs of the examination subject. This has the following advantages. The examination subject will not feel uncomfortable because of temperature, thus the user's experience of the MRI system is enhanced. By the same token, the comfortable temperature increases the examination subject's ability to undergo examinations of high SAR and long duration. Evidently, the comfortable temperature also reduces medical risks associated with overheating of the body: for example, in some cases, high absorption of RF energy will lead to reddening or even burning of the skin. With the ventilation device based on particular embodiment 1 of the present invention, heat will be rapidly dissipated, thereby lowering the incidence of such risks. Many examination subjects are distressed during nuclear magnetic resonance examinations, and a flow of air can help to reduce such distress and the sense of being confined. However, with existing ventilation devices, the operator will sometimes forget to switch on the ventilation device or the fan rotation speed is too low; with the ventilation device based on particular embodiment 1 of the present invention, the airflow is automatically adjusted in the default state, and an optimized airflow can significantly reduce the distress felt by examination subjects.

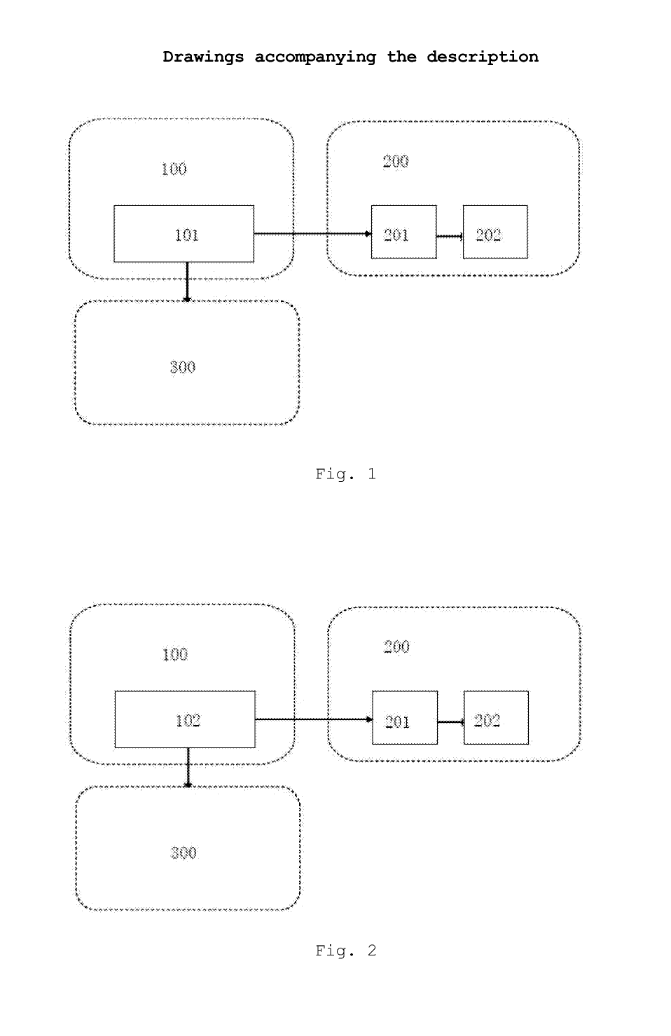

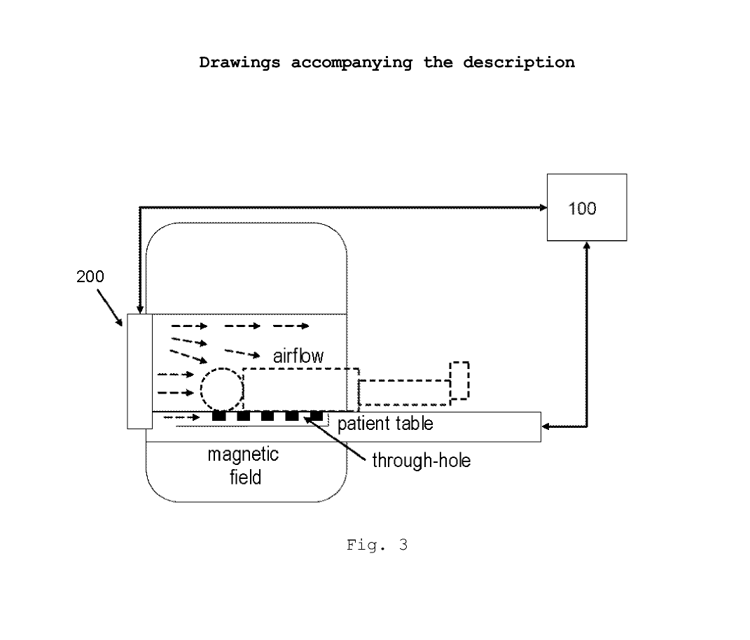

FIG. 2 is a schematic diagram of an MRI system according to particular embodiment 2 of the present invention. The MRI system comprises a main computer 100, a ventilation device 200 and an imaging device 300, wherein the main computer 100 is connected to the ventilation device 200 and the imaging device 300 separately. The main computer 100 comprises a bodily sign detection component 102, which detects the body temperature, pulse or another bodily sign of the examination subject. By means of the connection between the main computer 100 and the ventilation device 200, the bodily sign detection component 102 sends the above bodily sign signal to the ventilation device 200 as a heat signal. The ventilation device 200 comprises an adjustment component 201 and a fan 202. By means of the connection between the main computer 100 and the ventilation device 200, the adjustment component 201 receives the above signal from the bodily sign detection component 102 of the main computer 100, and adjusts the airflow generated by the fan 202 of the ventilation device 200 according to the above signal, i.e. the body temperature, pulse or other bodily sign of the examination subject. At the same time, the main computer 100 outputs a command for a scanning sequence to the imaging device 300, which subjects the examination subject to magnetic resonance imaging according to the scanning sequence. Preferably, the ventilation device 200 further comprises a refrigeration component, for refrigerating the airflow generated by the fan 202.

On the basis of the body temperature of the examination subject, the adjustment component 201 adjusts the strength, direction and temperature of the airflow generated by the fan 202 of the ventilation device 200. If, on the basis of the signal from the bodily sign detection component 102, the ventilation device 200 judges that the body temperature of the examination subject is too high, the pulse is too fast or another bodily sign is abnormal, i.e. judges that the body temperature of the examination subject is higher than and/or equal to a specified threshold or that the pulse is faster than and/or equal to a specified threshold, this indicates that the examination subject needs to be cooled; thus the ventilation device 200 will adjust the fan 202 to take heat away from the surface of the examination subject's body in an optimal manner, thereby ensuring the comfort of the examination subject. The adjustment component of the ventilation device 200 can accomplish this task in one or more of the following ways, singly or in combination: (1) increasing the strength of the airflow, (2) adjusting the direction of the airflow, (3) lowering the temperature of the airflow. If, on the basis of the signal from the bodily sign detection component 102, the ventilation device 200 judges that the body temperature of the examination subject is not high, the pulse is not fast or another bodily sign is abnormal, i.e. judges that the body temperature of the examination subject is within a specified threshold range or that the pulse is within a specified threshold range, this indicates that the examination subject either does not require cooling or requires to be heated; thus the ventilation device 200 will adjust the operating parameters of the fan in the opposite direction, thereby ensuring the comfort of the examination subject. In addition to default options for automatic adjustment, the operator may adjust the ventilation device manually if the examination subject has special needs.

The bodily sign detection component 102 is already widely used in nuclear magnetic resonance imaging systems, and can measure the body temperature of the examination subject by means of a temperature sensor. Moreover, in existing magnetic resonance devices, most bodily sign detection components 102 rely on an optical sensor to measure the pulse of the examination subject using the relationship between blood oxygen concentration and light absorption. The bodily sign detection component 102 may also measure the pulse of the examination subject by means of a pressure sensor, and detect other bodily signs of the examination subject by means of various other sensors.

In the ventilation device according to particular embodiment 2 of the present invention, operating parameters of the fan are adjusted according to the needs of the examination subject. This has the following advantages. The examination subject will not feel uncomfortable because of temperature, thus the user's experience of the MRI system is enhanced. By the same token, the comfortable temperature increases the examination subject's ability to undergo examinations of high SAR and long duration. Evidently, the comfortable temperature also reduces medical risks associated with overheating of the body: for example, in some cases, high absorption of RF energy will lead to reddening or even burning of the skin. With the ventilation device based on particular embodiment 2 of the present invention, heat will be rapidly dissipated, thereby lowering the incidence of such risks. Many examination subjects are distressed during nuclear magnetic resonance examinations, and a flow of air can help to reduce such distress and the sense of being confined. However, with existing ventilation devices, the operator will sometimes forget to switch on the ventilation device or the fan rotation speed is too low; with the ventilation device based on particular embodiment 2 of the present invention, the airflow is automatically adjusted in the default state, and an optimized airflow can significantly reduce the distress felt by examination subjects.

Once the MM system with a ventilation device according to particular embodiment 1 and particular embodiment 2 of the present invention has been set up, the area of contact between the examination subject and the patient table is still not within the region of coverage of the flow of air. FIG. 3 is an MRI system with a ventilation device according to particular embodiment 1 and particular embodiment 2. As FIG. 3 shows, channels or through-holes are provided on the patient table of the MRI system for the airflow outputted by the ventilation device to pass through, as a result of which the airflow covers the area of contact between the examination subject and the patient table. The channels are located on that surface of the patient table which is in contact with the examination subject; the through-holes are perpendicular to that surface of the patient table which is in contact with the examination subject. The channels or the through-holes may be formed by molding or by a mechanical method; such channels and through-holes do not affect the strength or insulation of the patient table.

The present invention proposes a ventilation device for an MRI system, and an MRI system in which the ventilation device is used. The ventilation device comprises a fan and an adjustment component, wherein the fan is used to generate a flow of air past an examination subject in the MRI system, and the adjustment component is used to adjust an operating parameter of the fan according to a heat signal indicating variation of heat in the examination subject. The ventilation device and MRI system comprising the same according to the present invention enhance the user's experience of the MRI system, increase the examination subject's ability to undergo examinations of high SAR and long duration, and reduce medical risks associated with overheating of the body.

The above embodiments are merely preferred embodiments of the present invention, and are by no means intended to limit it. Any modifications, equivalent substitutions or improvements etc. made without departing from the spirit and principles of the present invention should fall within the scope of protection thereof.

1. A ventilation device for a magnetic resonance imaging (MRI) system, comprising:
a fan adapted to generate an airflow past an examination subject in the MRI system; and
an adjustment component adapted to adjust an operating parameter of the fan according to a heat signal indicating variation of heat in the examination subject.

2. The ventilation device as claimed in claim 1, wherein the heat signal comprises an energy signal outputted by a specific absorption rate monitoring and prediction component of the MRI system.

3. The ventilation device as claimed in claim 2, wherein the energy signal comprises RF energy that is already absorbed by the examination subject and/or RF energy that will be absorbed by the examination subject.

4. The ventilation device as claimed in claim 1, wherein the heat signal comprises a bodily sign signal outputted by a bodily sign detection component of the MRI system.

5. The ventilation device as claimed in claim 4, wherein the bodily sign signal comprises body temperature and/or pulse of the examination subject.

6. The ventilation device as claimed in claim 1, wherein the ventilation device is located at both ends or at bottom of a patient table of the MRI system.

7. The ventilation device as claimed in claim 1, wherein the operating parameter comprises an airflow strength, an airflow direction, or an airflow temperature.

8. The ventilation device as claimed in claim 1, further comprising a refrigeration component adapted to refrigerate the airflow generated by the fan.

9. An magnetic resonance imaging (MRI) system, comprising:
a patient table; and
a ventilation device as claimed in claim 1.

10. The MRI system as claimed in claim 9,
wherein the patient table comprises at least one airflow channel and/or at least one airflow through-hole,
wherein the airflow channel is located on a surface in contact with the examination subject and serves to permit a passage of an airflow, and
wherein the airflow through-hole is perpendicular to a surface in contact with the examination subject and serves to permit the passage of an airflow.
